(19) United States
(12) Patent Application Publication
(10) Pub. No.: US 2018/0041202 A1
(43) Pub. Date: Feb. 8, 2018

(54) Overload Protection Circuitry

(71) Applicant: MACOM Technology Solutions Holdings, Inc., Lowell, MA (US)

(72) Inventor: Sebastien Douyere, Saint Laurent Du Var (FR)

(21) Appl. No.: 15/229,565

(22) Filed: Aug. 5, 2016

(51) Int. Cl. H03K 17/082; H04N 5/378; H01L 27/02

(52) U.S. Cl. CPC H03K 17/0822; H01L 27/0255; H01L 27/0266; H04N 5/378

(57) ABSTRACT

A system for protecting a camera driver circuit from a static discharge during cable connection is disclosed comprises a supply node having a supply voltage for a driver circuit and a ground on a ground node for the driver circuit. A resistor network is configured to receive a voltage from the supply node and generate a sensed voltage that is related to the voltage on the supply node. An amplifier or comparator compares the sensed voltage to a threshold voltage, and if the sensed voltage is greater than the threshold voltage, generate a control signal. A variable resistor is configured to receive the control signal and responsive to the control signal, establish a conductive path, or vary a resistance of the conductive path, between the supply node and the ground node, thereby shunting current through the conductive path from the supply node to the ground node.

### 1. FIELD OF THE INVENTION

The innovation relates to protection circuitry and in particular to a method and apparatus for protecting circuitry from voltage over stress (EOS).

### 2. RELATED ART

Transmission of an electrical signal between locations is a common event in signal processing system. One such application is in a transmission path between a camera and a broadcast truck. This may occur at any location that uses cameras which are coupled through wires or cables to a remote location, such as a truck with processing or broadcast capability or a video processing room or equipment.

FIG. 1 illustrates an exemplary video link between a camera and broadcast equipment. In a typical video application, a link is made of a BNC cable 104 (which length varies between 1 meter and 200 meters) that is AC coupled on one side to a cable driver 108 that is part of a transmitter, such as in, but not limited to, a camera 116, and AC coupled to a receiver 112 (video processing equipment) on the opposing end, such as at a broadcast truck. AC coupling occurs due to capacitors 126A, 126B as shown. As presented, the output of the cable driver 108 is single ended, and AC coupled to its load.

The link may include a SDI (Serial Digital Interface) protocol. With this protocol the signal can be transmitted with optical fibers or with 75 coaxial cables 104 as shown. The coaxial cable solution is preferred because of its lower cost and its robustness (it can be bent, people can walk on it, and the like). In addition, the cable length can be as long as several hundred meters.

A 75 ohm termination impedance at both the transmitter (camera) 116 and receiver (truck) 112 is shown by impedance elements 120A, 120B. A cable equalizer 122 is provided at the receiver 112 to perform equalization and amplification of the received signal to establish the signal for subsequent video processing.

To transmit the signal through such a cable 104, a cable driver 108 is used. One functional goal of the cable driver 108, which may be implemented on an integrated circuit (chip) located on a printed circuit board is to ensure that the signal at the input of the coaxial cable 104 complies with the SMPTE standard. The SMTPE standard defines rise and fall times, output swing, output return loss and other important signal characteristics.

FIG. 2A illustrates a prior art signal plot of the received signal over time. This signal plot 204 is often referred to as an eye diagram, such that the open center area defined by the plot is referred to as an ‘eye’. When selecting a cable driver, customers often demand uncompromising precision in the output signal. As shown in FIG. 2A, the eye opening 208 is open, but infringed by the signal thereby narrowing or disturbing the centrally located eye. This is a drawback to the prior art from at least a customer perception standpoint.

Another drawback to the prior art is that in prior art cable systems with associated drivers and receivers, due to external electro-magnetic parasitics, a high voltage step can be generated inside the cable. Based on in-lab testing, this voltage step can be 5V or more and can last more than 29 ms (which is much longer than an ESD stress 150).

A uniform and known test is provided to determine a system resistance to EOS (Voltage Over Stress) situations. The EOS (Voltage Over Stress) test quantifies the maximum voltage level the chip will be able to support during a given amount of time on its terminal without being damaged. This voltage level is usually above the normal operation conditions of the device. Camera manufacturers place a high value on the results of the EOS test for the high speed output nodes. Indeed, in the real application, the cable driver can be damaged by a large capacitive charge, which may be caused by cable length, or by an EMI (Electro Magnetic Interferences) caused by external disruptions. The net effect of an EOS event is damage to the device.

The innovation disclosed below overcomes the drawbacks of the prior art and provides additional benefits.

### SUMMARY

To overcome the drawbacks of the prior art and provide additional benefits, a system for protecting a camera driver circuit from a static discharge during cable connection is disclosed. In one embodiment, the system comprises a supply node having a supply voltage for a driver circuit and a ground on a ground node for the driver circuit. This embodiment also includes a resistor network coupled to receive a voltage from the supply node and generate a sensed voltage, the sensed voltage related to the voltage on the supply node. An amplifier or comparator is configured to compare the sensed voltage to a threshold voltage, and responsive to the sensed voltage being greater than the threshold voltage, generate a control signal. A variable resistor is coupled between the supply node and the ground node such that the variable resistor is configured to receive the control signal and responsive to the control signal, establish a conductive path or vary a resistance of the conductive path between the supply node and the ground node, thereby shunting current from the supply node to the ground node.

The variable resistor may comprise a transistor. The amplifier may comprise an operational amplifier. The variable resistor may comprise a switch. In one embodiment, the threshold voltage is variable based on a user input. The system may also include one or more diodes connected in series between the supply node and the ground node.

Also disclosed is a system for protecting a cable driver circuit in a camera from a voltage over stress condition to protect one or more circuit elements from damage due to the voltage over stress condition. In this exemplary embodiment the system comprises a comparator configured to compare a sensed voltage to a threshold voltage, and responsive to the sensed voltage being greater than the threshold voltage, generating a control signal. The sensed voltage comprises a voltage on a driver voltage supply node or a voltage proportional to the voltage on the driver voltage supply node. Also part of this embodiment is a variable resistor configured to receive the control signal. Responsive to the control signal the variable resistor establishes a conductive path or varies a resistance of the conductive path to shunt current away from the driver voltage supply node.

In one configuration the comparator comprises an amplifier. The variable resistor may comprise a switch. It is contemplated that the current is shunted from the driver voltage supply node to ground as the sensed voltage increases above the threshold voltage. The system may further comprise a resistor network configured as a voltage divider to receive the voltage on a driver voltage supply node and create the sensed voltage.

A system for protecting a driver circuit from damage resulting from an over-voltage condition is disclosed. In one embodiment, the system comprises one or more drivers, each driver having one or more driver input signals and one or more driver output signals. A comparator is configured to receive a threshold signal and a sensed signal. The sensed signal is proportional to at least one driver output. The comparator also compares the threshold signal to the sensed signal to generate an over-voltage condition signal such that the over-voltage conditional signal is indicative of when an over-voltage condition is occurring. The comparator provides the over-voltage condition signal to a controller, and the controller is configured to disable one or more drivers responsive to the over-voltage condition signal to prevent damage to the driver circuit.

This system may further comprise a logic element configured to receive the over-voltage condition signal and a power down enable signal, the logic element configured to output a power down signal to one or more of the one or more drivers to disable one or more components in the driver circuit to prevent damage to the driver circuit when the over-voltage condition signal indicates an over-voltage is present. It is further contemplated that the system may also include two or more resistors coupled to at least one driver output. The two or more resistors form a voltage divider network configured to receive a driver output signal and form the sensed signal. In one configuration the one or more driver output signals are common mode signal.

A method is also disclosed and described herein for protecting a driver circuit from a stress over voltage condition. In one embodiment, this method comprises generating a sensed voltage where the sensed voltage is proportional to a driver supply voltage, on a supply node and the supply voltage comprising a supply voltage and a voltage stress over voltage, if present. This method also processes the sensed voltage and a threshold voltage with a comparator and, responsive to the comparison, generates a control signal. Responsive to the control signal, a variable resistance is generated between the supply node and a ground node, the resistance value based on the sensed voltage thereby allowing current to travel from the supply node to the ground node.

In one embodiment, the comparator comprises an operational amplifier. It is contemplated that the variable resistance may be generated by a FET and the control signal provided to the FET increases as the sensed voltage increases in magnitude beyond the voltage threshold. The sensed voltage is related to a voltage on a driver voltage supply node in relation to a ground node. The variable resistance may be an open circuit or a short circuit between the supply node and the ground node.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The components in the figures are not necessarily to scale, emphasis instead being placed upon illustrating the principles of the invention. In the figures, like reference numerals designate corresponding parts throughout the different views.

FIG. 1 illustrates an exemplary video link between a camera and broadcast equipment.

FIG. 2A illustrates a prior art signal eye diagram plot.

FIG. 2B illustrates a preferred signal plot showing the eye diagram for the innovation disclosed herein.

FIG. 3 illustrates a block diagram representation of a last stage of the camera circuit system during an EOS event with protection diodes added.

FIG. 4 illustrates an exemplary block diagram of an EOS protection circuit.

FIG. 5 illustrates an alternative or supplementary embedment of an EOS event detector.

FIG. 6 illustrates a plot of maximum EOS voltage in relation to EOS clamp threshold Vth based on exemplary lab results for a given implementation.

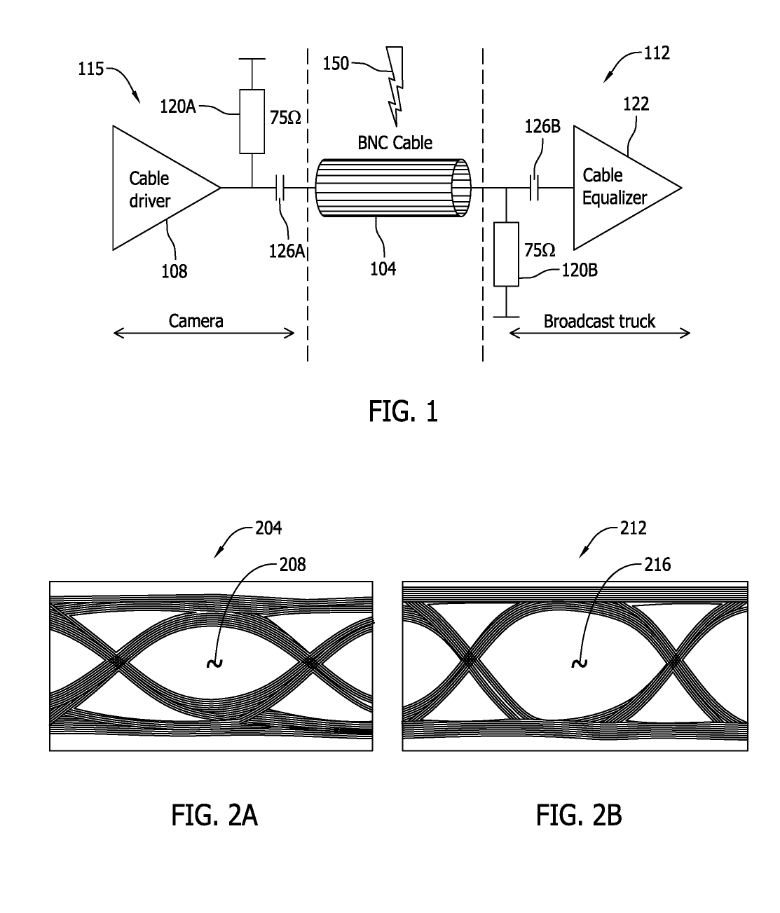

### DETAILED DESCRIPTION

FIG. 2B illustrates a preferred signal plot 212 showing the eye diagram 216 based on lab testing for the innovation disclosed herein. As compared to the plot shown in FIG. 2A, the eye opening is improved and preferred because the central eye is more open and more clearly defined as compared to the plot of FIG. 2A. It should be noted that the eye diagrams are presented to highlight the extent to which importance is placed on the output eye quality. A customer will prefer having the eye of FIG. 2B in their system and as the eye degrades and closes beyond that shown in FIG. 2A, system operation will be affected.

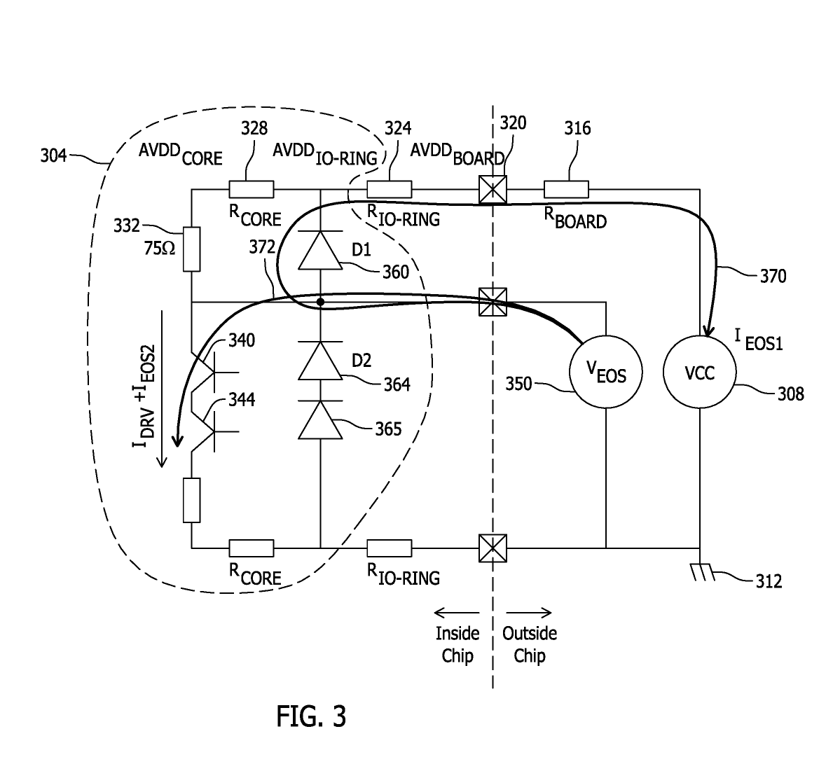

FIG. 3 illustrates a block diagram representation of an EOS event in a camera circuit system 304 with protection diodes added. The cable driver circuit can be modeled with elements 344, 360 and 332. The elements 344 and 332 are the half of the CML differential pair and its resistive load. Only the half of the circuit has been represented in order to simplify the drawing. The element 344 is the tail current source of the CML differential pair. This is a simplified version provided for purposes of discussion and to show the effect of EOS (voltage over stress). This EOS event can be modeled by a perfect pulse generator with a low impedance connected just after the AC coupling cap. The amplitude of the pulse is the defined herein an EOS to apply to the part. During the EOS, because of the AC coupling cap, the driver can see on its pin a voltage higher than its supply voltage. For example, if the supply voltage is 2.5V, and if the EOS stress is 5V, the voltage seen on the driver node will be slightly lower than 2.5V+5V=7.5V. Such a high stress can damage the components within the driver, such as ESD protection diodes and transistors. Indeed, during this voltage stress, the stressed IO sees its voltage increasing (or decreasing depending of the sign of the voltage step) and being higher than the supply voltage (7.5V in our example) forcing the protection diodes to turn ON and to drive a high current. The order of magnitude is in the one to two ampere range into the supply. Due to on-chip and on-board parasitic resistors, such as elements 316, 324, and 328 in FIG. 3, on the supply network, the supply voltage seen inside the core of the chip (core supply voltage) will increase causing its value to be higher than the breakdown voltage of integrated components. As a result, those components (FET transistors, capacitors, diodes . . . ) will be damaged.

As a consequence, the chip must be protected against this kind of stress. The quantification of this protection is based on the maximum EOS voltage the chip will be able to handle without being damaged. One goal of this solution is to make sure that inside the integrated circuit, the difference between ground, on a ground node, and the supply voltage on a supply node will not exceed a given value during the EOS stress. In general, embedded inside the core of the chip is a circuit configured to ensure that the voltage difference between the supply node and the ground node will not exceed a given value and this value is programmable or adjustable.

Continuing with FIG. 3, illustrated is a block diagram representation of a system 304. As shown, the Vcc source 308 is the driver supply voltage. It is coupled to or referenced from ground 312 as shown. Advancing from the Vcc supply 308 is a board resistance Rboard 316. The board resistance 316 represents the resistance of the PCB. AVDDboard voltage is created due to the board resistance 316, AVDDio-ring voltage is created due to the resistance R 324 from the IO-Ring 324. The IO-Ring may be inside the chip. The voltage AVDDcore is created due to the core resistance Rcore 328 of the integrated circuit (chip). The representation of the 75 ohm impedance 332 is provided for impedance matching. Voltage AVDDcore is the supply voltage Vcc to the driver which is defined as Vcc minus AVDDboard and AVDDioRing. Rcore is resistance of the core of circuit inside integrated circuit.

Driver elements 340 and 344 are shown which create two currents respectfully, namely I_{EOS2} and I_{DRV}. I_{EOS2} is the current absorbed by the element 340 during an EOS event. The drivers 340, 344 are shown as transistors. The board resistance 316 represents the resistance of the PCB.

Also shown in FIG. 3 is an EOS voltage, shown as VEOS supply 350 that represents an EOS event. This element is not part of the signal but shown to represent the EOS voltage which couples in from a cable. The EOS voltage enters the integrated circuit and contributes to the current passing through the drivers 340, 344, which is referred to as IEOS2. The EOS voltage creates the current I_{EOS2}. The supply voltage creates the I_{DRV} current, which is defined by element 344 as shown in FIG. 3. Element 344 is the slave side of the NPN current mirror. Both of the I_{EOS2} and I_{DRV} flow to ground 312 as shown during an EOS event, otherwise, only I_{DVR} flows to ground. The dashed lines 370 represents I_{EOS1} and the dashed line 372 represents I_{EOS2}.

FIG. 3 also shows protection diodes D1 360 and diode D2 364. Prior art embodiment only included a single diode D1 360. The addition of diode D2 364 provides additional EOS protection. Two diodes in series instead of D2 364 provides additional EOS protection.

During an EOS event, such as when a cable is connected to a camera, a high DC voltage VEOS is applied to the cable driver output node due to the discharge. In order to simplify the analysis, the AC coupling cap will be assumed as a short during the stress and is thus not shown in FIG. 3. During this event, IEOS1 and IEOS2 can be huge, such as several amperes in magnitude. Thus, according to the value of VEOS, one or more components may break. For example, if VEOS is too high, then the diode D2 may exceed its breakdown voltage and cause damage to the circuit. If VEOS is high enough, the diode D1 may exceed its maximum current capabilities, which again causes damage to the circuit. Furthermore, if IEOS1 is high enough, then the AVDDCORE−AVSSCORE value may be higher than 3.6V which is the highest voltage beyond the 3.3 volts that the FETs can see between any of its 2 terminals (due to the current flowing from the EOS voltage source to the VCC supply voltage source by the path composed of D1, RIO-RING and RBOARD. For other technology and designs other voltage values or elements may be used or realized. In addition, if VEOS is high enough, and depending of the IDRV+IEOS2 current, the driving transistor 340 may exceed its VCE breakdown voltage, thereby damaging the circuit.

Stated another way, during a voltage over stress condition, all the current goes from the modeled EOS voltage source 350 to the supply through the diodes 360, 364 and the supply resistive network. If, for example, the current is 2 A, the on chip supply (core supply voltage) will be increased by 0.9V (assuming the parasitic resistors annotated on the pictures) which can damage the internal circuits of the driver and the diodes 360, 364 (between the output node and GND). As shown, the EOS event can be modeled by a voltage pulse generator 308 with a low impedance connected just after the AC coupling cap. The amplitude of the pulse is the defined herein as an EOS voltage stress which is applied to the driver. During the EOS stress, because of the AC coupling cap, the driver can see on its pin a voltage higher than its supply voltage, such as for up to 30 milliseconds. For example, if the nominal supply voltage is 2.5V, and if the EOS stress is 5V, the voltage seen on the driver node will be slightly lower than 2.5V+5V=7.5V. Such high stress can and will damage the drivers, diodes and possibly other parts. During this stress, the stressed I/O sees its voltage increasing (or decreasing depending of the sign of the voltage step) and being higher than the supply voltage (7.5V in our example) forcing the protection diodes 360, 364 to turn ON and to drive a high current (the order of magnitude is an ampere) into the supply 308. Due to on chip and on board parasitic resistors on the supply network, the supply voltage seen inside the core of the chip (core supply voltage) will increase. Its value can be higher than the breakdown voltage of integrated components. As a result, those components (FET transistors, capacitors, diodes . . . ) will be damaged.

In order to improve the robustness of the cable driver, all the items of the previous discussion must have a protection. The goal of this solution is to make sure that for the driver circuit and its related protection elements, the difference between ground and supply voltage does not exceed a given value during the EOS stress. It is proposed that to overcome the drawbacks of the prior art and provide further protection, the following steps and design changes are proposed.

In order to prevent the diode D2 364 to exceed its breakdown voltage, another diode will be added in series with diode D2. Thus, diode D1 360 is present in prior solutions but the single diode may be supplemented with two diodes 364, 365 in series, which will result in 3 diodes in series between AVDD and the ground node. As a result, during an EOS event, the diodes will see a voltage equal to VEOS/2 between their 2 terminals. This reduced the voltage across D2 by half, thereby greatly reducing the likelihood of damage.

To further prevent the high supply voltage value, EOS protection circuits are proposed to be added. These circuits will include a detection mechanism such that if AV DDCORE−AV SSCORE is higher than a given threshold (tunable), then the EOS protection circuitry will be engaged which will short or otherwise divert the AVDDCORE value to AVS SCORE and then force some current to return to ground through AVS SCORE resulting in the reduction of the difference between AV DDCORE−AV S SCORE and AV DDIO-RING−AV SSIO-RING. This protects the transistors 340, 344, which may be FET or bipolar transistors, inside the core of the IC, and also the ESD diodes 360, 364 by limiting the voltage drop across their terminals to a value lower than their breakdown limit.

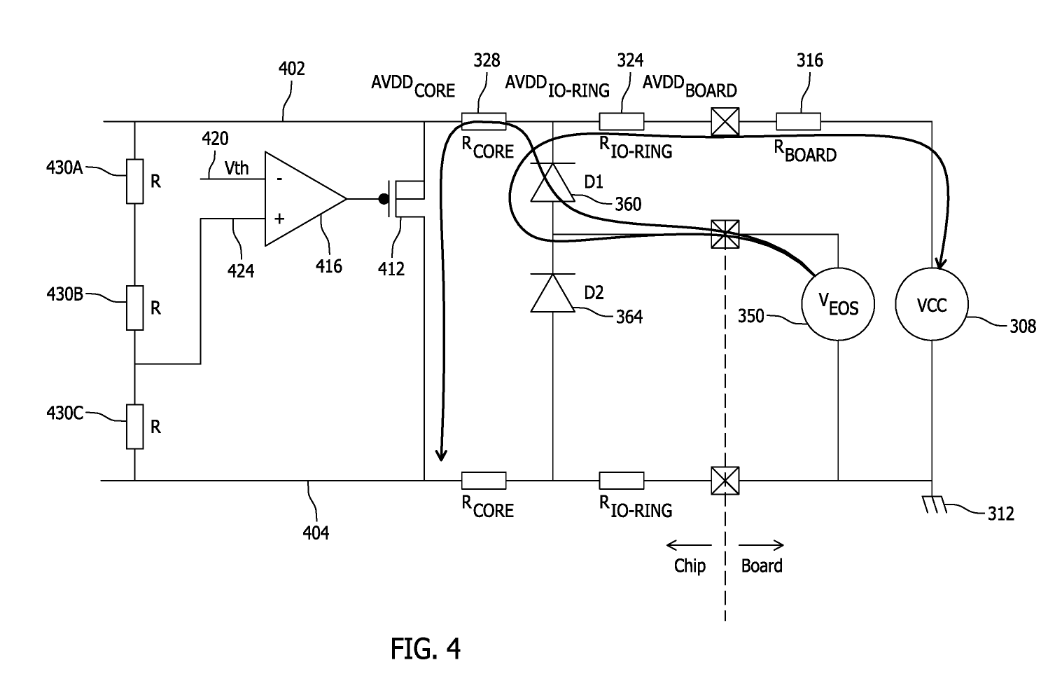

FIG. 4 illustrates an exemplary block diagram of an EOS protection circuit. This is but one possible embodiment and one of ordinary skill in the art may arrive at different circuit layouts based on this disclosure, but such varying circuit layout should not be considered as departing from the scope of the claims. As compared to FIG. 3, like elements are identified with the same reference numbers and the discussion of these elements set forth in FIG. 3 is incorporated for FIG. 4. In other instances, some elements are omitted to avoid confusion but these omitted elements may be included in implementation.

In this embodiment a logic element, such as a FET, PFET, or NFET (FET) 412 is located between a top rail 402 and a bottom rail 404. A group of series connected resistors 430A, 430B, and 430C are connected between the top rail 402 and the bottom rail 404. Although shown as three resistors, any number of resistors can be used and various configurations of resistors and voltage divider networks are contemplated. A processor, executing non-transitory machine executable code stored on a memory, may also be used to control the FET 412 or create the control voltage.

The resistors 430 create a voltage divider network such that a conductor connects to a node 424 between resistor 430B and resistor 430C. Also connected to node 424 is a comparator. In this example embodiment the comparator comprises an operational amplifier 416. A second input 420 to the operational amplifier 416 provides a reference or threshold voltage Vth. The output of the operational amplifier 416 serves as an input to the FET 412. The other circuitry used for video processing and driving the signal may be located to the left of the resistor 430.

In operation, during normal modes of operation, when an EOS event is not present, or occurring, the system operates as is known. In particular, the voltage on the top rale 402 is not excessive or beyond the level defined in the standard. As such, the voltage on node 424 is at a first level, which is compared to the threshold voltage Vth by the operational amplifier. Responsive to this comparison, the operational amplifier outputs a control signal to the FET 412. During normal operation the voltage on the top rail 402, when divided by the voltage divider of the resistors 430, is less than the threshold voltage Vth, thereby causing the operational amplifier to output a zero or low magnitude control signal. This control signal, when presented to the FET 412 causes the FET to be maintained in an off position, thereby establishing an open circuit. This prevents current from flowing through the FET 412 ensuring normal circuit operation. It is contemplated that Vth is independent of AVDDcore to prevent Vth from increasing during an EOS event.

In the event of an EOS event, the voltage on the top rail will increase, due to the increased amperes flowing in the circuit. The increased current causes an increase in voltage at the top rail, thereby creating an increase in voltage differential between the top rail 402 and the bottom rail 404. This increase in voltage differential creates a corresponding increase in voltage on the sensing node 424, such as to a second level. The voltage on node 424 may be referred to as Vsense. If the magnitude of the EOS event is such that the voltage magnitude at operation amplifier input node 424 is greater than the second input 420, which presents Vth to the operational amplifier 416, then the output of the operational amplifier will increase, thus increasing the control signal to the FET 412. This in turn causes the FET 416 to turn on causing a conductive path to be established between the top rail 402 and the bottom rail 404. As a result of the conductive path established trough the FET 412, the voltage difference between 402 and 404, is reduced and controlled in order to remain below the threshold value. This lower voltage difference allows to save the diodes 360,364, other circuit components such as the drivers 340, 344 shown in FIG. 3 from being damaged.

It is contemplated that in one embodiment the voltage (Vsense) on node 424 does not exceed the break down voltage of the op amp. This prevents circuit damage.

A further advantage of this proposed solution, is that it is not sensitive to the duration of the EOS overload, which has been shown during testing to last for a very long time, such as a couple minutes. This is due to the fact that the proposed protection is based on a feedback loop circuit (which is not the case of the classical ESD clamp). The feedback loop continues to shunt current to ground for as long as the EOS event is occurring.

In various embodiments, responsive to the control input from the operational amplifier 416, the FET 416 may act as a switch, thereby establishing an open circuit or a short circuit between the top rail 402 and the bottom rail. The FET 412 may also be configured to create a variable resistance between the top rail 402 and the bottom rail 404 such that the resistance value is based on and related to the magnitude of the output from the operational amplifier. In one embodiment of EOS protection circuit, if the voltage difference between the on chip supply voltage and the ground 312 is higher than a given threshold (for example, supply voltage plus 0.4V), then the EOS protection circuitry will drive some current from top rail (supply voltage) through the FET 412 to ground node 312 which will increase the absolute value of the on chip ground, due to parasitic resistors Rcore and Rio-ring on the bottom rail, and thus decrease the on chip voltage difference between ground and the top rail (supply voltage).

It is contemplated that the system is tunable such that the threshold voltage may be varied or controlled, either in real time or by a control setting, to determine the magnitude of the EOS event that will trigger the shunt to ground. Likewise, the resistor network that establishes the voltage divider network may be varied to or controlled, either in real time or by a control setting, to change the behavior of the circuit operation to determine the magnitude of the EOS event that will trigger the shunt to ground. Both factors may also be controlled to in turn control the FET to act as a variable resistor.

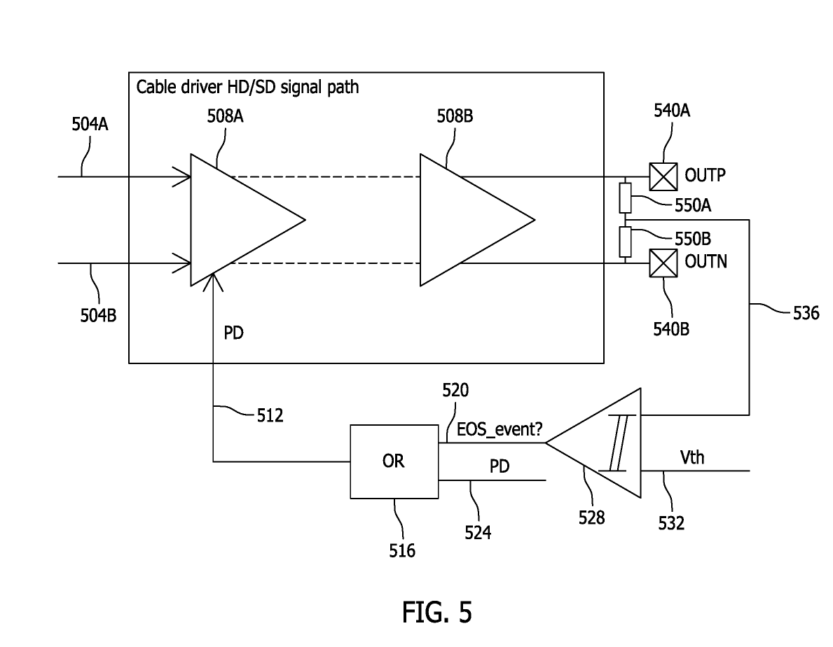

FIG. 5 illustrates an alternative or supplementary embedment of an EOS event detector. The FIG. 5 embodiment that may be implemented in addition to or instead of the protection circuit shown in FIG. 4. This extra implementation is an EOS detector. This circuit can also tell the user if an EOS event is being seen, or has been seen before (real time alarm and latched alarm). In this embodiment a power down feature is used to quickly power down the system in the event of an EOS event. As shown, input 504A and 504B may comprise positive and negative inputs to a driver 508A. One or more drivers 508B may be in series to generate an output at nodes 540A, and 540B. Cross coupled between the outputs 540A, 540B are resistors 550A, and 550B which for a signal node 536. The signal on node 536 represents a common mode signal that is the signal being sensed for an EOS condition. The signal on node 536 is presented as an input to a comparator 528. Although shown as a comparator, element 528 could also be a logic element, op amp, or FET. The other comparator input is input 526 which provides a threshold voltage signal Vth to the comparator 528.

The voltage threshold Vth may be the same as or different than the threshold voltage shown in FIG. 4. It is contemplated that the Vth value may be fixed or variable, and if variable, it may be adjusted automatically in response to circuit operation or by a user or technician. The threshold voltage is a signal or magnitude which defines when an EOS condition is occurring. It may be tunable or adjustable by the system or the user.

The output of the comparator 528 serves as an input to an OR gate 516 or other logic element on an input 520. The other input 524 to the OR gate compresses a power down signal. The output of the OR gate 516 connects to the drivers on path 512.

In operation, the cable driver(s) 508 amplify the signal in accordance with normal operation. The output drive signal presented on outputs 540A, 540B generates the sensed signal on node 536. The sensed signal on node 536 is related to the output signals 540A, 540B. The comparator 528 compares the sensed signal to the threshold voltage (or any threshold signal) that is provided to the comparator. If the sensed signal is smaller than the threshold voltage value, then system operation occurs without change.

If the sensed signal is larger than the threshold voltage value, then the comparator generates an EOS event signal on comparator output 520. The EOS event signal is a signal indicating that an EOS event is sensed. The EOS event signal is presented to the OR gate 516. The power down (PD) signal is also provided to the OR gate 516. Responsive to the EOS event signal going to a high logic level or otherwise acting as a control signal, the OR gate 524 outputs the power down signal to the cable driver 508 or otherwise causes driver circuitry to power down or enter a protection mode to prevent the EOS event from damaging the driver circuit or other aspect of the system. In one embodiment the power down functionality occurs within 10 nanoseconds.

It is contemplated that the power down signal is controllable, such that it is user controllable to either be enabled or disabled. This allows the user or system to selectively determine whether the system may be powered down due to an EOS event. Control circuitry may be embedded inside the core of the chip which will cause the voltage difference between the supply and the ground to not exceed a given value and this value may be programmable. It is also contemplated that this feature may be disabled. Alternatively, the output of the comparator output may function as the power down signal that is provided to the driver 508.

In summary, to prevent the driving bipolar transistors (drivers) from any breakdown failures or damage, the output common mode of the cable driver is sensed. If the sensed voltage on node 536 is higher than a given threshold voltage Vth, then an EOS event is detected which will power down the entire channel. This will make the current flowing into the driving transistors zero, which will then improve the transistor breakdown performances. The bipolar transistor breakdown voltage is dependent on the amount of current flowing inside it. The more current flowing, the lower will be the breakdown voltage value. By powering down the driver as soon as an EOS event is detected, the current flowing inside the bipolar transistors (I_{DVR} on FIG. 3) is set to 0 mA which maximize their breakdown voltage and thus their reliability during an EOS event.

It is also contemplated that other aspects or components of the circuit may be shut down instead of, or in addition to, the driver or transistor. For example, the power down signal may actuate or control a switch that prevents the EOS from reaching and damaging the circuit. It is further contemplated that the power down circuitry may be embodied completely in a digital embodiment.

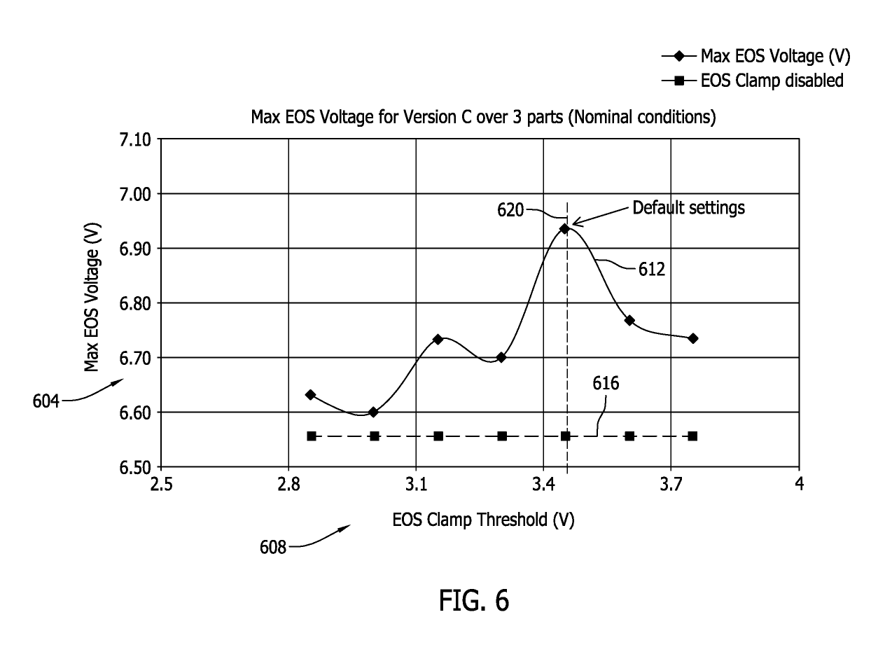

FIG. 6 illustrates a plot of maximum EOS voltage in relation to EOS clamp threshold Vth. This is but one exemplary signal plot of an exemplary embodiment. The vertical axis 604 represents maximum EOS voltage that the chip can support for a given threshold and the horizontal axis 608 represents EOS clamp threshold voltage (Vth). The maximum EOS voltage when the protections are enabled or disabled are respectively the solid line plot 612 and the dashed line plot 616. As shown, the dash line plot 616 shows that with the protection system disabled, the maximum EOS voltage which may be encountered is about 6.57 volts. Beyond this value, the circuit is damaged. As an improvement over the prior art, the plot 612 shows the improvement of about 8%. As shown the plot 612 shows that the maximum EOS voltage rises to almost 7 volts. Note that in FIG. 6 the solid line plot 612 curve is always higher than the dashed line plot, meaning that the EOS performances are always better with the EOS protection circuitry active than without. The maximum difference is about 0.4V. Then it can be seen that there is an optimum point 620 for the EOS Protection threshold with the threshold voltage set to about 3.45 volts which yields the largest maximum EOS voltage. Below approximately 3.4V, the EOS protection circuit is engaged too early which increases the current flowing through diode D1 (FIGS. 3 & 4). As is understood by one of ordinary skill in the art, for the technology embodiments in which the invention has been integrated, the optimum point is about 3.4V. This result can be different for another type of integrated circuit technology and voltage levels. This diode then drives a current exceeding its current limit which would harm it. Above approximately 3.4V, the EOS protection circuit is engaged too late which destroys the driver (in this particular case, the voltage across D2 exceed its breakdown value which will harm it).

As a further benefit to the innovation over prior art system, it functions over variations in temperature and supply voltage. Based on lab testing, the maximum EOS voltage is always lower when the protection circuitry enabled for all temperature and supply condition cases. As a result, the EOS protection circuitry behaves as expected by controlling the voltage difference between AV DDCORE−AV S SCORE. Moreover, the EOS performance does not drift significantly with variations in the supply voltage value or temperature. To the extent any change was detected, this slight drift is not due to the EOS protection because the performance without the EOS protection in place also displays the same drift. The variation is due to the breakdown voltage variation of the diodes with temperature.

While various embodiments of the invention have been described, it will be apparent to those of ordinary skill in the art that many more embodiments and implementations are possible that are within the scope of this invention. In addition, the various features, elements, and embodiments described herein may be claimed or combined in any combination or arrangement.

What is claimed is:

1. A system for protecting a camera driver circuit from a static discharge during cable connection, the system comprising:
providing a supply voltage, on a supply node, for a driver circuit and providing a ground on a ground node for the driver circuit;
a resistor network, coupled to the supply node to receive a voltage from the supply node and generate a sensed voltage, the sensed voltage related to the voltage on the supply node;
an amplifier or comparator configured to compare the sensed voltage to a threshold voltage, and responsive to the sensed voltage being greater than the threshold voltage, generate a control signal; and
a variable resistor coupled between the supply node and the ground node, the variable resistor configured to receive the control signal and responsive to the control signal, establish a conductive path or vary a resistance of the conductive path between the supply node and the ground node, thereby shunting current from the supply node to the ground node.

2. The system of claim 1 wherein the variable resistor comprises a transistor.

3. The system of claim 1 wherein the amplifier comprises an operational amplifier.

4. The system of claim 1 wherein the variable resistor comprises a switch.

5. The system of claim 1 wherein the threshold voltage is variable based on a user input.

6. The system of claim 1 further comprising one or more diodes connected in series between the supply node and the ground node.

7. A system for protecting a cable driver circuit in a camera from an voltage over stress condition to protect one or more circuit elements from damage from the voltage over stress condition, the system comprising:
a comparator configured to compare a sensed voltage to a threshold voltage, and responsive to the sensed voltage being greater than the threshold voltage, generating a control signal, wherein the sensed voltage comprises a voltage on a driver voltage supply node or a voltage proportional to the voltage on the driver voltage supply node; and
a variable resistor configured to receive the control signal and responsive thereto, establish a conductive path or vary a resistance of the conductive path to shunt current away from the driver voltage supply node.

8. The system of claim 7, wherein the comparator comprises an amplifier.

9. The system of claim 7, wherein the variable resistor comprises a switch.

10. The system of claim 7, wherein current is shunted from the driver voltage supply node to ground as the sensed voltage increases above the threshold voltage.

11. The system of claim 7, further comprising a resistor network configured as a voltage divider to receive the voltage on a driver voltage supply node and create the sensed voltage.

12. A system for protecting a driver circuit from damage resulting from an over-voltage condition, the system comprising:
one or more drivers, each driver having one or more driver input signals and one or more driver output signals;
a comparator configured to;
receive a threshold signal and a sensed signal, the sensed signal proportional to at least one driver output;
compare the threshold signal to the sensed signal to generate an over-voltage condition signal, the over-voltage conditional signal indicative of when an over-voltage condition is occurring;
provide the over-voltage condition signal to a controller, the controller configured to disable one or more drivers responsive to the over-voltage condition signal to prevent damage to the driver circuit.

13. The system of claim 12 further comprising a logic element configured to receive the over-voltage condition signal and a power down enable signal, the logic element configured to output a power down signal to one or more of the one or more drivers to disable one or more components in the driver circuit to prevent damage to the driver circuit.

14. The system of claim 12 further comprising two or more resistors coupled to at least one driver output, the two or more resistors forming a voltage divider network configured to receive a driver output signal and form the sensed signal.

15. The system of claim 12 wherein the one or more driver output signals are common mode signal.

16. A method for protecting a driver circuit from a stress over voltage condition, the method comprising:
generating a sensed voltage, the sensed voltage proportional to a driver supply voltage, on a supply node, the supply voltage comprising a supply voltage and a voltage stress over voltage, if present;
processing the sensed voltage and a threshold voltage with a comparator and, responsive to the comparison, generating a control signal; and
responsive to the control signal, generating a variable resistance between the supply node and a ground node, the resistance value based on the sensed voltage.

17. The method of claim 16 wherein the comparator comprises an operational amplifier.

18. The method of claim 16 wherein the variable resistance is generated by a FET and the control signal provided to the FET increases as the sensed voltage increases in magnitude beyond the voltage threshold.

19. The method of claim 16 wherein the sensed voltage is related to a voltage on a driver voltage supply node and a ground node.

20. The method of claim 16 wherein the variable resistance is an open circuit or a short circuit between the supply node and the ground node.
